(19) United States
(12) Patent Application Publication
(10) Pub. No.: US 2026/0337453 A1
(43) Pub. Date: Oct. 29, 2026

(54) CATIONIC COPOLYMER CMP COMPOSITION

(71) Applicant: ENTEGRIS, INC., Billerica, MA (US)

(72) Inventors: Tamil Sakthivel, Aurora, IL (US); Steven Grumbine, Aurora, IL (US)

(21) Appl. No.: 19/657,953

(22) Filed: Apr. 24, 2026

Related U.S. Application Data
(60) Provisional application No. 63/794,055, filed on Apr. 24, 2025.

(51) Int. Cl. C09G 1/02; H10P 52/40

(52) U.S. Cl. CPC C09G 1/02; H10P 52/402

(57) ABSTRACT

A chemical mechanical polishing composition comprises, consists of, or consists essentially of a liquid carrier, colloidal silica particles dispersed in the liquid carrier, and a silicon containing polymer covalently bonded to a surface of the colloidal silica particles. The polymer has a first acrylate silane or acrylamide silane group and a second positively charged nitrogen containing group such that the colloidal silica particles have a positive charge in the polishing composition.

### BACKGROUND OF THE INVENTION

Chemical mechanical polishing (CMP) compositions and methods for polishing (or planarizing) the surface of a substrate are well known. Polishing compositions (also known as polishing slurries, CMP slurries, and CMP compositions) for polishing various metal (such as tungsten) and non-metal (such as silicon oxide) layers on a semiconductor substrate may include abrasive particles suspended in an aqueous solution and various chemical additives such as oxidizers, chelating agents, catalysts, topography control agents, buffers, and the like.

In a conventional CMP operation, the substrate (wafer) to be polished is mounted on a carrier which is in turn mounted on a carrier assembly and positioned in contact with a polishing pad in a CMP polishing tool. The carrier assembly provides a controlled pressure to the substrate against the polishing pad. The substrate and pad are moved relative to one another by an external driving force. The relative motion of the substrate and pad abrades and removes a portion of the material from the surface of the substrate, thereby polishing the substrate. The polishing of the substrate by the relative movement of the pad and the substrate may be further aided by the chemical activity of the polishing composition and/or the mechanical activity of an abrasive suspended in the polishing composition.

In many CMP operations achieving optimum planarization and/or planarization efficiency is of critical importance. For example, in tungsten CMP operations excessive oxide erosion and/or dishing may lead to difficulties in subsequent lithography steps as well as cause electrical contact problems that can degrade electrical performance. Achieving such optimum planarization with a minimum of defects may also be of critical importance as polishing defects are known to negatively impact electrical performance. Despite many advances to commercial CMP slurries, there remains a need in the industry for CMP slurries (or compositions), such as tungsten CMP slurries, that provide for improved planarity and reduced defects during a CMP operation.

### BRIEF SUMMARY OF THE INVENTION

A chemical mechanical polishing composition is disclosed. The composition comprises, consists of, or consists essentially of a liquid carrier, colloidal silica particles dispersed in the liquid carrier, and a silicon containing polymer covalently bonded to a surface of the colloidal silica particles, the polymer having a first acrylate silane or acrylamide silane group and a second positively charged nitrogen containing group such that the colloidal silica particles have a positive charge in the polishing composition.

### DETAILED DESCRIPTION OF THE INVENTION

Chemical mechanical polishing compositions and methods for using those compositions to polish a substrate are disclosed. In one example embodiment, a chemical mechanical polishing composition comprises, consists essentially of, or consists of an aqueous based liquid carrier, colloidal silica particles dispersed in the liquid carrier, and a silicon containing polymer covalently bonded to a surface of the colloidal silica particles, the polymer having a first acrylate silane or acrylamide silane group and a second positively charged nitrogen containing group such that the colloidal silica particles have a positive charge in the polishing composition. The pH of the composition may be less than 5 when used for tungsten or molybdenum CMP applications. A method for polishing a metal (e.g., tungsten or molybdenum) containing substrate includes contacting the substrate with the polishing composition, moving the polishing composition relative to the substrate, and abrading the substrate to remove a portion of at least one metal layer from the substrate and thereby polish the substrate.

The polishing composition contains polymer modified colloidal silica particles suspended (dispersed) in a liquid carrier. As used herein the term polymer modified colloidal silica particles refers to colloidal silica particles that are modified with (e.g., covalently bonded with) a silicon containing polymer having first and second groups; a first acrylate silane or acrylamide silane group that is covalently bonded with the colloidal silica and a second positively charged nitrogen containing group such that the colloidal silica particles have a positive charge in the polishing composition.

In some example embodiments, the polymer is a copolymer having first and second comonomers. The first comonomer includes the acrylate silane or acrylamide silane group and the second comonomer includes the positively charged nitrogen containing group. In other example embodiments, the polymer has a monomer that has both the acrylate silane or acrylamide silane group and the positively charged nitrogen containing group. In such embodiments, the acrylate silane or acrylamide silane group is covalently bonded with the colloidal silica.

It has been found that the disclosed polishing compositions including copolymer modified colloidal silica particles as described herein advantageously achieve improved patterned wafer performance and particularly improved erosion performance as compared to polishing compositions including conventional colloidal silica particles (colloidal silica particles that are not polymer or copolymer modified).

The polymer or copolymer (referred to herein as simply polymer for simplicity) modified colloidal silica particles may include substantially any suitable colloidal silica particles. In other words, substantially any suitable colloidal silica particles may be polymer modified and used in the disclosed polishing compositions. In preferred embodiments, the colloidal silica particles are nonporous. As used herein the term colloidal silica particles refers to silica particles that are prepared via a wet process rather than a pyrogenic or flame hydrolysis process which produces structurally different particles. The colloidal silica may be precipitated or condensation-polymerized silica, which may be prepared using any method known to those of ordinary skill in the art, such as by the sol gel method or by silicate ion-exchange. Condensation-polymerized silica particles are often prepared by condensing Si(OH)₄ to form substantially spherical particles.

The polymer modified colloidal silica particles may have substantially any suitable average particle size as measured using a CPS Disc Centrifuge Particle size analyzer (e.g., Model DC24000 HR available from CPS Instruments, Prairieville, Louisiana). Note that as used herein the average particle size is taken to be the D50 of the measured distribution. In example embodiments, the polymer modified colloidal silica particles may have an average particle size in a range from about 5 nm to about 300 nm (e.g., from about 10 nm to about 250 nm, from about 20 nm to about 200 nm, from about 25 nm to about 200 nm, from about 40 nm to about 200 nm, or from about 40 nm to about 160 nm).

The polymer modified colloidal silica particles may have substantially any suitable surface area. For example, the polymer modified colloidal silica particles may further be characterized as having a BET surface area in a range from about 20 m²/g to about 200 m²/g (e.g., in a range from about 30 m²/g to about 180 m²/g, from about 40 m²/g to about 160 m²/g, or from about 50 m²/g to about 150 m²/g). The BET surface area may be measured, for example, as described in Colloids and Surfaces A: Physicochem. Eng. Aspects 322 (2008) 248-252.

The polymer modified colloidal silica particles may have substantially any suitable aspect ratio. The aspect ratio of a colloidal silica particle is defined herein as the maximum caliper diameter of the particle divided by the minimum caliper diameter of the particle (hence the aspect ratio is always greater than or equal to 1). For example, the polymer modified colloidal silica particles may further be characterized as having a number average aspect ratio in a range from about 1 to about 2 (e.g., from about 1 to about 1.8, from about 1 to about 1.6, or from about 1.1 to about 1.5). The number average aspect ratio represents a statistical measure of the average (median) aspect ratio of the colloidal silica particles in the polishing composition (on a number rather than a weight basis). The number average aspect ratio may be referred to as AR50 since statistically half (50%) of the particles have an aspect ratio less than the median value and half (50%) of the particles have an aspect ratio greater than the median value.

The number average aspect ratio of the colloidal silica particles in a polishing composition may be determined by evaluating a large number of particles in high magnification transmission electron microscopy (TEM) images (e.g., at a magnification in a range from about 10,000 to about 30,000). To obtain a statistically significant median aspect ratio it is generally necessary to measure and compute the aspect ratio for a large number of colloidal silica particles (e.g., at least 500 or more particles or even 1000 or more particles) using a plurality of images (e.g., at least 10 or more images, 15 or more images, or even 20 or more images). The maximum caliper diameter and the minimum caliper diameter of each of the particles may be measured manually (particle by particle), for example, using the scale bar on the TEM image. However, a user-guided automated process is practically preferred based upon the requirement to evaluate a large number of particles. Such automated processes preferably make use of commercially available image analysis software.

The polymer modified colloidal silica particles may have substantially any suitable degree of aggregation. In other words, the polymer modified colloidal silica particles may be aggregated, partially aggregated, and/or non-aggregated. For example, in some embodiments, a portion of the particles may be aggregated and the remainder may be non-aggregated. Non-aggregated particles are individually discrete particles (commonly referred to in the art as primary particles or primaries) that are generally spherical or nearly spherical in shape. Aggregated particles are particles in which multiple primary particles are clustered or bonded together to form aggregates having generally irregular or non-spherical shapes (such as elongated or branched). Non-aggregated (primary) particles may also be referred to herein as monomers. Aggregated particles may also be referred to as dimers (having two primaries), trimers (having three primaries), tetramers (having four primaries), and so on.

In example embodiments, the polymer modified colloidal silica particles may be substantially non-aggregated in that they include mostly primary particles. In other embodiments, the polymer modified colloidal silica particles may be partially aggregated. By partially aggregated it may be meant that 50 percent or more of the polymer modified colloidal silica particles include two or more aggregated primary particles or that 30 percent or more (or 45 percent or more) of the colloidal silica particles include three or more aggregated primary particles. In still other embodiments, the polymer modified colloidal silica particles may have an aggregate distribution in which 20 percent or more of the polymer modified colloidal silica particles include less than three primary particles (i.e., non-aggregated primary particles or aggregated particles having just two primary particles, also referred to as monomers and dimers) and 50 percent or more of the polymer modified colloidal silica particles include three or more aggregated primary particles.

Partially aggregated colloidal silica abrasives may be prepared, for example, using a multi-step process in which primary particles are first grown in solution, for example as described in U.S. Pat. No. 5,230,833. The pH of the solution may then be adjusted to an acidic value for a predetermined time period to promote aggregation (or partial aggregation), for example, as described in U.S. Pat. No. 8,529,787. An optional final step may allow for further growth of the aggregates (and any remaining primary particles).

In example embodiments, the polishing composition may include a mixture of at least first and second colloidal silica particles. The mixture may include, for example, a mixture of first polymer modified colloidal silica particles and second colloidal silica particles that may or may not be polymer modified. In some example embodiments, both the first and second colloidal silica particles may be polymer modified colloidal silica particles. In example embodiments including first and second colloidal silica particles, the first polymer modified colloidal silica particles may be characterized as having an aspect ratio of less than about 1.25 (e.g., less than about 1.2 or less than about 1.15) and the second colloidal silica particles may have an aspect ratio of greater than about 1.25 (e.g., greater than about 1.3 or greater than about 1.35). Moreover, in such embodiments, the first polymer modified colloidal silica particles may have a particle size that is greater than about 80 nm (e.g., greater than about 90 nm or greater than about 100 nm) and the second colloidal silica particles may have a particle size in a range from about 30 nm to about 80 nm (e.g., from about 30 to about 60).

The polymer modified colloidal silica particles may advantageously have a high purity. For example, the polymer modified colloidal silica particles may have a total metals impurity (in which the metals include sodium, aluminum, calcium, magnesium, and the transition metals) of less than 20 parts per million (e.g., less than 15 ppm, less than 10 ppm, less than 5 ppm, less than 2.5 ppm, or less than 1 ppm). In such embodiments, the particles may be potassium or ammonia stabilized. The silica (e.g., colloidal silica) may further have a total metals impurity (in which the metals include potassium, sodium, iron, aluminum, calcium, magnesium, titanium, nickel, chromium, copper, and zinc) of less than 20 parts per million (e.g., less than 15 ppm, less than 10 ppm, less than 5 ppm, less than 2.5 ppm, or less than 1 ppm). In such embodiments, the particles may be ammonia or amine stabilized.

In the disclosed embodiments, the colloidal silica particles may include substantially any suitable commercially available colloidal silicas. Those of ordinary skill in the art will readily appreciate that colloidal silicas having a wide range of physical properties are commercially available from a large number of vendors, for example, including Nissan Chemical Industries, Ltd., Nalco Holding Company, W.R. Grace and Company, Fuso Chemical Company, Nouryon, Nyacol Nano Technologies, Inc., Tama Chemicals Company, and JGC Holdings Corporation.

The disclosed polishing composition may include substantially any suitable amount of the polymer modified colloidal silica particles. For example, the polishing composition may include about 0.01 wt. % or more polymer modified colloidal silica particles at point of use (e.g., about 0.05 wt. % or more, about 0.1 wt. % or more, or about 0.2 wt. % or more). The amount of polymer modified colloidal silica particles in the polishing composition may include about 5 wt. % or less at point of use (e.g., about 3 wt. % or less, about 2 wt. % or less, about 1.5 wt. % or less, or about 1 wt. % or less) Accordingly, it will be understood that the amount of polymer modified colloidal silica particles may be in a range bounded by any two of the aforementioned endpoints, for example, in a range from about 0.01 wt. % to about 5 wt. % at point of use (e.g., from about 0.05 wt. % to about 5 wt. %, from about 0.1 wt. % to about 3 wt. %, from about 0.1 wt. % to about 2 wt. %, or from about 0.2 wt. % to about 1 wt. %).

The polymer modified colloidal silica particles may be modified with substantially any suitable polymeric material having the above described first and second groups. For example, the polymer may include styrene, acrylamide, acrylate and methacrylate, olefin, vinyl ester, and/or acrylonitrile monomers as well as other monomers that may be polymerized by radical polymerization. The polymer is preferably not a polyether. The polymer may be homopolymer or a copolymer (including any number of different monomers). In advantageous embodiments, the polymer includes a silicon containing monomer, for example, including silicon containing substituted and/or unsubstituted vinyl, acrylamide, acrylate, and/or methacrylate monomers. It will, of course, be understood that the monomers are precursors that may undergo hydrolysis and condensation during treatment of the colloidal silica particles.

The polymer may include a monomer having both (i) an acrylate silane or an acrylamide silane group that is covalently bonded with the colloidal silica and (ii) a positively charged nitrogen containing group. The monomer may include, for example, an amine group such as a primary amine, a secondary amine, a tertiary amine, or a quaternary amine group (such as a betaine group). Example monomers include N-(3-methacryloxy-2-hydroxyalkyl)-3-aminopropyltrialkoxysilane, 3-(Acryloxypropyl)-N-(3-aminopropyl)trialkoxysilane, N-(2-Aminoethyl)-3-acryloxypropyltrialkoxysilane, N-(3-Trialkoxysilylpropyl)-N′-(2-aminoethyl)acrylamide, and N-(3-Trialkoxysilylpropyl)-N-methylacrylamide. The polymer may alternatively include a copolymer having a first comonomer that includes the acrylate silane or acrylamide silane group covalently bonded with the colloidal silica and a second comonomer that includes the positively charged nitrogen containing group. In such copolymer embodiments the second comonomer advantageously does not include a silicon atom.

In copolymer embodiments, a first monomer may include the acrylate silane or an acrylamide silane group that is covalently bonded with the colloidal silica and a second comonomer may include a nitrogen atom. In such embodiments, the second comonomer may include, for example, an amine group such as a primary amine, a secondary amine, a tertiary amine, or a quaternary amine group (such as a betaine group). Preferred embodiments include a quaternary amine group. In advantageous embodiments, the comonomer may include a quaternary amine group containing acrylate or methacrylate comonomer, such as 2-(N,N-dialkylamino)ethyl methacrylate, 3-[(3-acrylamidopropyl)dialkylamminio]propanoate, and/or 2-(methacryloyloxy)ethyl dialkyl-(3-sulfopropyl)ammonium hydroxide. The copolymer advantageously includes a sufficient amount of the second comonomer such that the colloidal silica particle is positively charged in the polishing composition but not so much of the second comonomer so as to destabilize the colloidal silica during the polymerization.

In example embodiments, the copolymer advantageously includes a sufficient amount of the second comonomer such that the zeta potential of the colloidal silica particles in the composition is at least 10 mV (e.g., at least 15 mV, at least 20 mV, at least 25 mV, or at least 30 mV). In advantageous embodiments, the zeta potential of the colloidal silica particles in the composition is at least 15 mV and is preferably at least 25 mV. For the purposes of this disclosure the zeta potential is as measured in the point of use polishing composition (with the exception that the composition does not include hydrogen peroxide) using the electroacoustic method via the Colloidal Dynamics Zetaprobe Analyzer® (with no Smoluchowski correction applied).

It will be appreciated that the nitrogen containing comonomer (the second comonomer) may also increase the isoelectric point (IEP) of the polymer modified colloidal silica particles (e.g., as compared to unmodified colloidal silica or as compared to a polymer modified colloidal silica in which the polymer includes only the first monomer). In example embodiments, the amount of the second comonomer may be sufficient such that the IEP of the disclosed polymer modified colloidal silica is at least about 5 (e.g., at least about 6, or at least about 7). For the purposes of this disclosure the IEP is measured on the polymer modified colloidal silica before the addition of other polishing composition compounds (e.g., the iron-containing accelerator). The dispersion of the polymer modified colloidal silica particles is diluted in deionized water to a polymer modified colloidal silica concentration in a range from 2 to 5 weight percent. The diluted sample is titrated with 0.1N potassium hydroxide for a base titration (sample pH to 10.5). The zeta potential is measured using a Zetaprobe Analyzer® at least every 0.5 pH units during the titration. The IEP is identified by determining the pH value at which the zeta potential is 0 mV. The precise IEP value may be computed via interpolation between the pH values at which the zeta potential transitions from positive to negative.

In preferred embodiments, the polymer may be covalently bonded with the surface of the silica particles. The term covalent (as in covalently bonded) is used in its ordinary sense herein. Such covalent bonding between the colloidal silica particles and the polymer may be evident (or identified), for example, from the methodology used to synthesis the copolymer modified particles. Covalent bonding may also be evident (or identified), for example, when the silicon containing compounds remain bonded to the colloidal silica particles after flushing, dilution, filtration, and the like.

The disclosed cationic copolymers may include substantially any suitable molar ratio of the first and second comonomers to achieve the desired positive charge. For example, to obtain a sufficiently high charge, the amount of the second comonomer may be greater than about 2 mole percent (e.g., greater than about 4 mole percent, greater than about 6 mole percent, greater than about 8 mole percent, or greater than about 10 mole percent). To maintain stability during synthesis, the amount of the second comonomer may be less than about 60 mole percent (e.g., less than about 50 mole percent, less than about 40 mole percent, less than about 35 mole percent, or less than about 30 mole percent). Accordingly the molar ratio of the second comonomer to the first comonomer may be in a range bounded by any two of the aforementioned endpoints, for example, from about 2 mole percent to about 60 mole percent (e.g., from about 4 mole percent to about 50 mole percent, from about 8 mole percent to about 40 mole percent, or from about 10 mole percent to about 30 mole percent).

The polymer modified colloidal silica may be synthesized, for example, via admixing an initiator (such as a radical initiator) with an aqueous dispersion of monomer modified colloidal silica particles (e.g., colloidal silica particles that are covalently bonded with the silicon containing monomer). As described above, preferred monomers include a polymerizable group on one end and a silicon containing group on another end (e.g., an acrylate, methacrylate, or acrylamide group on one end and a trialkoxysilyl group on the other end). In such embodiments, the silicon containing monomer may be covalently bonded to the surface of the colloidal silica particle, for example, via a condensation reaction between the silicon containing group (e.g., a trialkoxysilyl group) in the monomer and surface silanol group(s) on the colloidal silica particle. The bonded monomer may then be polymerized via the addition of the initiator.

In embodiments including a copolymer modified colloidal silica, the initiator may be admixed with an aqueous dispersion of first comonomer modified colloidal silica (in which the silicon containing first comonomer is covalently bonded to the surface of the colloidal silica). The second comonomer may be added to the dispersion with or before the initiator. For example, in one embodiment, the second comonomer and the initiator may be added together (at the same time). In another embodiment, the second comonomer may be admixed with the aqueous dispersion of first comonomer modified colloidal silica. The initiator may then be added to the mixture to obtain the copolymer modified colloidal silica. In still another embodiment, the first and second comonomers may be admixed with the colloidal silica to obtain the dispersion of first comonomer modified colloidal silica. The initiator may then be added to obtain the copolymer modified colloidal silica. One example copolymerization procedure is described in more detail below (and in Example 1).

The disclosed polymer or copolymer modified colloidal silica may have a theoretical modification level of the polymer of at least 20 percent (e.g., at least 25 percent, at least 30 percent, or at least 40 percent). As used herein, the modification level of the polymer is defined as the ratio of the number silicon atoms in the polymer (e.g., the number of monomer or first comonomer units) to the number of the available surface silanol groups on the colloidal silica. For the purposes of this disclosure, the number of the available silanol groups on the colloidal silica may be estimated to be 4.5 per nm² of surface area. The modification level of the polymer may be determined theoretically (a theoretical modification level) from the amount of the first comonomer added during synthesis and the total surface area of the silica particles. A measured modification level may be determined, for example, via a total (or percent) carbon measurement and knowledge of the molecular formula of the first and second comonomers. The theoretical modification level may be close to the measured modification level when most of the added silane monomer bonds with the silica particles and the amount left in solution is insignificant (e.g., less than about 10 percent of the amount added, less than about 5 percent of the amount added, less than about 2 percent of the amount added, or less than about 1 percent of the amount added).

While the disclosed embodiments are not limited in this regard, it will be appreciated that in certain example embodiments, the disclosed polymer modified colloidal silica particles may be thought of as having a core shell structure in which the polymer forms an outer shell (or partial outer shell) about the colloidal silica core. The polymer shell may have a uniform or non-uniform thickness. Such embodiments may also be thought of as possessing an interface at which the polymer shell is covalently bonded to the colloidal silica core.

The disclosed polymer modified colloidal silica may optionally be further modified with a positively charged compound to enhance the positive charge on the polymer modified colloidal silica in the composition. For example, the positively charged polymer modified colloidal silica may optionally be further modified with an aminosilane compound. By further modified it is meant that the positively charged compound is bonded with an external surface of the polymer modified colloidal silica (e.g., to the polymer or to the colloidal silica). For example, an aminosilane compound may be covalently bonded with free Si—OH groups, or other similar groups, on the colloidal silica and/or with free Si—OH groups, or other similar groups, on the polymer. In such optional embodiments, the polymer modified colloidal silica may be further modified with substantially any suitable aminosilane compound that enhances the positive charge and/or increases the IEP of the particles.

In example embodiments, the modification level of the polymer or copolymer may be estimated via a Sear's titration (e.g., as described below in Example 2). The procedure for making a Sear's titration follows the method described in G.W. Sears, Jr., Analytical Chemistry, 28(12), 1981 (1956). More specifically, in the Sears method, using a 1% by mass silica dispersion, a titration is performed with a 0.1M sodium hydroxide solution. The Sear's number may be determined using the following equation:

$$Sear ' s \# = \frac{60.2 \cdot V}{A \cdot SSA}$$

where Sear's #represents the amount of titratable species (such as the silanol group density in units of OH/nm²), V represents the volume (in ml) of 0.1M NaOH needed to raise the pH from 4 to 9 (the Sear's titration), A represents the mass of the silica (in grams), and SSA represents the BET surface area of the silica (in m²/g). If significant amounts of other titratable species are present in the pH range from about 4 to about 9 they should be removed (e.g., via ion exchange, dialysis, ultrafiltration, etc.).

In advantageous embodiments, the Sear's number (also referred to as a silanol number or a silanol density) of the polymer or copolymer modified colloidal silica particles may be less than about 2 OH/nm² (e.g., less than about 1.8 OH/nm², less than about 1.6 OH/nm², less than about 1.5 OH/nm², less than about 1.4 OH/nm², less than about 1.2 OH/nm², or less than about 1 OH/nm²).

The modification level of the polymer or copolymer may also be estimated via measuring the total (or percent) carbon in the polymer modified colloidal silica particles. It will be appreciated that the polymer or copolymer contain carbon (while the colloidal silica particles usually contain little or no carbon) such that a measure of the total carbon may be taken as a measure of the modification level. As disclosed herein, the total carbon is estimated via combusting the copolymer modified colloidal silica particles in an oxygen rich environment and determining the amount of carbon in the particles from the amount of carbon dioxide generated during combustion. For example, samples of the polymer modified colloidal silica particles may be obtained via centrifugation, washing, and oven drying a corresponding dispersion. A known (measured) mass may then be combusted and the quantity of CO₂ determined via gas chromatography to determine the total carbon in each sample. When carbon containing compounds are present in solution, these carbon containing compounds should be removed from the solution prior to drying and combusting the particles (e.g., via centrifuge-wash-rinse cycles, ultra filtration, dialysis, etc.).

It will be appreciated that an increasing the modification level results in an increasing total carbon from the covalently bonded organics. In example embodiments, the polymer modified colloidal silica particles may have a total carbon of at least 0.5 percent (e.g., at least about 0.75 percent, at least about 1 percent, at least about 1.5 percent, or at least 2 percent). The amount of carbon may also be quantified based on the BET surface area of the colloidal silica particle, for example, as a number of carbon atoms per nm². In example embodiments, the polymer modified colloidal silica particles may have at least 10 carbon atoms per nm² of BET surface area (e.g., at least about 15 carbon atoms per nm², at least about 20 carbon atoms per nm², or at least about 25 carbon atoms per nm²).

In example embodiments, the copolymer modified colloidal silica particles in the polishing composition are substantially all copolymer modified colloidal silica particles. In other words, the polishing composition does not include a significant amount of silica particles or polymer particles other than the copolymer modified colloidal silica particles. By significant amount it is meant that less than about 1 percent (number fraction) of the abrasive particles (e.g. less than about 0.5%) are silica particles or polymer particles.

In other example embodiments, the polishing composition does not include a significant amount of fine (very small) particles. By fine it is meant particles having a particle diameter in a range from about 5 nm to about 25 nm. By significant amount it is meant that less than about 1 percent (number fraction) (e.g., less than about 0.5 percent or less than about 0.3 percent) of the abrasive particles are fine. The number of fine particles may be measured, for example, using differential mobility analysis (DMA).

A liquid carrier is generally used to facilitate the application of the copolymer modified colloidal silica particles and any optional chemical additives to the surface of the substrate to be polished. The liquid carrier may include any suitable carrier (e.g., a solvent) including lower alcohols (e.g., methanol, ethanol, etc.), ethers (e.g., dioxane, tetrahydrofuran, etc.), water, and mixtures thereof. Preferably, the liquid carrier comprises, consists essentially of, or consists of water, more preferably deionized water.

The polishing composition may be acidic or mildly acidic having a pH of less than about 6. The polishing composition may have a pH of about 1 or more (e.g., about 1.5 or more or about 2 or more). Moreover, the polishing composition may have a pH of about 7 or less (e.g., about 6 or less, about 5 or less, about 4.5 or less, about 4 or less, about 3.5 or less, or about 3 or less). According, the polishing composition may have a pH in a range bounded by any two of the aforementioned endpoints, for example, in a range from about 1 to about 7 (e.g., from about 1.5 to about 5, from about 1.5 to about 4, from about 2 to about 3.5, or from about 2 to about 3). In advantageous embodiments formulated for tungsten or molybdenum CMP applications, the composition may advantageously have a pH in a range from about 2 about 4 (e.g., from about 2 to about 3).

The pH of the polishing composition may be achieved and/or maintained by any suitable means. The polishing composition may include substantially any suitable pH adjusting agents or buffering systems. For example, suitable pH adjusting agents may include nitric acid, sulfuric acid, phosphoric acid, phthalic acid, citric acid, adipic acid, oxalic acid, malonic acid, maleic acid, ammonium hydroxide, and the like while suitable buffering agents may include phosphates, sulfates, acetates, malonates, oxalates, borates, ammonium salts, and the like.

Disclosed polishing compositions may include substantially any suitable chemical mechanical polishing additives, for example, including a chelating agent, a topography control agent, an etch inhibitor, an oxidizer, a polishing rate accelerator, a dispersant, and/or a biocide. Advantageous embodiments may be formulated for polishing tungsten, molybdenum, or other metal layers and may include, for example, an oxidizing agent, a polishing rate accelerating agent such as iron-containing accelerator, a topography control agent, and/or an etch inhibitor, however, the disclosed embodiments are not limited to tungsten and/or molybdenum polishing compositions or even to other metal polishing compositions. The disclosed embodiments may be utilized to polish substantially any dielectric or metal found in semiconductor devices.

In example embodiments, the disclosed polishing composition may be configured for polishing at least one metal layer. In such embodiments, the polishing composition may further include a metal polishing accelerator such as an oxidizer, a chelating or complexing agent, a catalyst, or any other suitable compound that increases the polishing rate of the metal layer. For example, an iron-containing compound may be used to increases the polishing rate of tungsten and/or molybdenum layers. The iron-containing compound may include a soluble iron-containing catalyst such as is disclosed in U.S. Pat. Nos. 5,958,288 and 5,980,775. Such an iron-containing catalyst may be soluble in the liquid carrier and may include, for example, ferric (iron III) or ferrous (iron II) compounds such as iron nitrate, iron sulfate, iron halides, including fluorides, chlorides, bromides, and iodides, as well as perchlorates, perbromates and periodates, and organic iron compounds such as iron acetates, carboxylic acids, acetylacetonates, citrates, gluconates, malonates, oxalates, phthalates, and succinates, and mixtures thereof.

An iron-containing accelerator may also include an iron-containing activator (e.g., a free radical producing compound) or an iron-containing catalyst associated with (e.g., coated or bonded to) the surface of the colloidal silica particle such as is disclosed in U.S. Pat. Nos. 7,029,508 and 7,077,880. For example, the iron-containing accelerator may be bonded with the silanol groups on the surface of the colloidal surface particles.

The amount of iron-containing accelerator in the polishing composition may be varied depending upon the oxidizing agent used and the chemical form of the accelerator. When the oxidizing agent is hydrogen peroxide (or one of its analogs) and a soluble iron-containing catalyst is used (such as ferric nitrate or hydrates of ferric nitrate), the catalyst may be present in the composition at point of use in an amount sufficient to provide a range from about 0.5 to about 3000 ppm Fe based on the total weight of the composition. For example, polishing compositions configured for bulk tungsten or molybdenum removal may include about 1 ppm Fe or more at point of use (e.g., about 5 ppm or more, about 10 ppm or more, or about 15 ppm or more). The polishing composition may include about 500 ppm Fe or less at point of use (e.g., about 200 ppm or less, about 100 ppm or less, or about 50 ppm or less). Accordingly, the point of use polishing composition may include Fe in a range bounded by any one of the above endpoints (e.g., from about 1 ppm to about 500 ppm, from about 5 ppm to about 200 ppm, from about 10 ppm to about 100 ppm, or from about 15 ppm to about 50 ppm). For tungsten or molybdenum buff applications that do not require high metal removal rates, the catalyst may be present in lower amounts, for example, from about 0.1 ppm to about 50 ppm Fe (e.g., from about 0.2 ppm to about 20 ppm or from about 0.2 to about 10 ppm) at point of use.

Embodiments of the polishing composition including an iron-containing accelerator may further include a stabilizer. Without such a stabilizer, the iron-containing accelerator and the oxidizing agent, if present, may react in a manner that degrades the oxidizing agent rapidly over time. The addition of a stabilizer tends to reduce the effectiveness of the iron-containing accelerator such that the choice of the type and amount of stabilizer added to the polishing composition may have a significant impact on CMP performance. The addition of a stabilizer may lead to the formation of a stabilizer/accelerator complex that inhibits the accelerator from reacting with the oxidizing agent, if present, while at the same time allowing the accelerator to remain sufficiently active so as to promote rapid tungsten or molybdenum polishing rates.

Useful stabilizers include phosphoric acid, organic acids such as polycarboxylic acids (e.g., dicarboxylic acids), phosphonate compounds, nitriles, and other ligands which bind to the metal and reduce its reactivity toward hydrogen peroxide decomposition and mixture thereof. The acid stabilizers may be used in their conjugate form, e.g., the carboxylate can be used instead of the carboxylic acid. The term “acid” as it is used herein to describe useful stabilizers also means the conjugate base of the acid stabilizer. Stabilizers can be used alone or in combination and significantly reduce the rate at which oxidizing agents such as hydrogen peroxide decompose.

Preferred stabilizers include phosphoric acid, acetic acid, phthalic acid, citric acid, adipic acid, oxalic acid, malonic acid, aspartic acid, succinic acid, glutaric acid, pimelic acid, suberic acid, azelaic acid, sebacic acid, maleic acid, glutaconic acid, muconic acid, ethylenediaminetetraacetic acid (EDTA), propylenediaminetetraacetic acid (PDTA), and mixtures thereof. The preferred stabilizers may be added to the compositions of this invention in an amount ranging from about 1 equivalent per iron-containing accelerator to about 3.0 weight percent or more (e.g., from about 1 equivalent to about 5 equivalents, or from about 3 equivalents to about 10 equivalents). As used herein, the term “equivalent per iron-containing accelerator” means one molecule of stabilizer per iron ion in the composition. For example, two equivalents per iron-containing accelerator means two molecules of stabilizer for each catalyst ion.

The polishing composition may optionally further include an oxidizing agent. The oxidizing agent may be added to the polishing composition during the slurry manufacturing process or just prior to the CMP operation (e.g., in a tank located at the semiconductor fabrication facility). Preferred oxidizing agents include inorganic or organic per-compounds. A per-compound as defined herein is a compound containing at least one peroxy group (—O—O—) or a compound containing an element in its highest oxidation state. Examples of compounds containing at least one peroxy group include but are not limited to hydrogen peroxide and its adducts such as urea hydrogen peroxide and percarbonates, organic peroxides such as benzoyl peroxide, peracetic acid, and di-t-butyl peroxide, monopersulfates (SO₅^{═}), dipersulfates (S₂O₈⁻), and sodium peroxide. Examples of compounds containing an element in its highest oxidation state include but are not limited to periodic acid, periodate salts, perbromic acid, perbromate salts, perchloric acid, perchlorate salts, perboric acid, and perborate salts and permanganates. The most preferred oxidizing agent is hydrogen peroxide.

The oxidizing agent may be present in the polishing composition in substantially any suitable amount, for example, from about 0.0 wt. % to about 20 wt. % at point of use. In example embodiments configured for bulk tungsten or molybdenum removal that include a hydrogen peroxide oxidizer and a soluble iron-containing catalyst, the oxidizer may be present in the polishing composition in an amount ranging from about 0.1 wt. % to about 10 wt. % at point of use (e.g., from about 0.5 wt. % to about 5 wt. % or from about 1 wt. % to about 4 wt. %). In example embodiments configured for buff tungsten or molybdenum applications, the amount of hydrogen peroxide in the composition is generally less, for example, from about 0 wt. % to about 1 wt. %.

The polishing composition may further include a metal etch inhibitor and/or a topography control agent. Suitable etch inhibitor compounds may inhibit the conversion of solid metal (such as solid tungsten or molybdenum) into soluble compounds while at the same time allowing for effective removal of the metal via the CMP operation. The polishing composition may include substantially any suitable inhibitor, for example, inhibitor compounds disclosed in commonly assigned U.S. Pat. Nos. 9,238,754; 9,303,188; and 9,303,189.

Example classes of compounds that that may be useful etch inhibitors include compounds having nitrogen containing functional groups such as nitrogen containing heteroycles, alkyl ammonium ions, amino alkyls, and amino acids. Useful amino alkyl corrosion inhibitors include, for example, hexylamine, tetraalkyl-p-phenylene diamine, octylamine, diethylene triamine, dialkyl benzylamine, aminoalkylsilanol, aminoalkylsiloxane, dodecylamine, mixtures thereof, and synthetic and naturally occurring amino acids including, for example, lysine, tyrosine, glutamine, glutamic acid, arginine, histidine, aspartic acid, cystine, and glycine (aminoacetic acid).

Suitable compounds may alternatively and/or additionally include an amine compound in solution in the liquid carrier. The amine compound (or compounds) may include a primary amine, a secondary amine, a tertiary amine, or a quaternary amine. The amine compound may further include a monoamine, a diamine, a triamine, a tetramine, or an amine based polymer having a large number of repeating amine groups (e.g., 4 or more amine groups).

Suitable compounds may alternatively and/or additionally include a cationic surfactant. The use of a cationic surfactant may advantageously reduce the metal etch rate and improve planarity (e.g., reducing dishing and/or erosion). In certain embodiments, the polishing compound may include a nitrogen containing cationic surfactant, such as a quaternary amine compound or a polyquaternary amine compound. By polyquaternary amine it is meant that the compound includes from 2 to 4 quaternary ammonium groups such that the polyquaternary amine is a diquaternary amine compound, a triquaternary amine compound, or a tetraquaternary amine compound. Diquaternary amine compounds may include, for example, N,N′-alkylenebis(dialkylteradecylammonium bromide), N,N,N′,N′,N′-pentaalkyl-N-tallow-1,3-propane-diammonium dichloride, N,N′-hexamethylenebis(trialkylammonium hydroxide), decamethonium bromide, didodecyl-tetraalkyl-1,4-butanediaminium diiodide, 1,5-dialkyl-1,5-diazoniabicyclo(3.2.2)nonane dibromide, dialkylcocoamine bis(chloroalkyl) ether diquaternary ammonium salt, and the like. Triquaternary amine compounds may include, for example, N(1),N(6)-didoecyl-N(1),N(1),N(6),N(6)-tetraalkyl-1,6-hexanediaminium diiodide. Tetraquaternary amine compounds may include, for example, methanetetrayltetrakis(tetraalkylammonium bromide). The polyquaternary amine compound may further include a long chain alkyl group (e.g., having 10 or more carbon atoms), For example, a polyquaternary amine compound having a long chain alkyl group may include N,N′-methylenebis(dialkyltetradecylammonium bromide), N,N,N′,N′,N′-pentaalkyl-N-tallow-1,3-propane-diammonium dichloride, didodecyl-tetraalkyl-1,4-butanediaminium di iodide, and N(1),N(6)-didodecyl-N(1),N(1),N(6),N(6)-tetraalkyl-1,6-hexanediaminium diiodide.

Suitable compounds may alternatively and/or additionally include a cationic polymer. Example cationic polymers include but are not limited to poly(vinylimidazolium), poly(methacryloyloxyalkyltrimethylammonium) chloride (polyMADQUAT), poly(diallyldimethylammonium) chloride (polyDADMAC) (e.g., Polyquaternium-6), poly(dialkylamine-co-epichlorohydrin), poly[bis(2-chloroethyl) ether-alt-1,3-bis[3-(dialkylamino)alkyl]urea] (e.g., Polyquaternium-2), copolymers of hydroxyalkyl cellulose and diallyldialkylammonium (e.g., Polyquaternium-4), copolymers of acrylamide and diallyldialkylammonium (e.g., Polyquaternium-7), quaternized hydroxyalkylcellulose ethoxylate (e.g., Polyquaternium-10), copolymers of vinylpyrrolidone and quaternized dialkylaminoalkyl methacrylate (e.g., Polyquaternium-11), copolymers of vinylpyrrolidone and quaternized vinylimidazole (e.g., Polyquaternium-16), Polyquaternium-24, a terpolymer of vinylcaprolactam, vinylpyrrolidone, and quaternized vinylimidazole (e.g., Polyquaternium-46), 3-Alkyl-1-vinylimidazolium alkyl sulfate-N-vinylpyrrolidone copolymer (e.g., Polyquaternium-44), and copolymers of vinylpyrrolidone and diallyldialkylammonium. Additionally, suitable cationic polymers include cationic polymers for personal care such as Luviquat® Supreme, Luviquat® Hold, Luviquat® UltraCare, Luviquat® FC 370, Luviquat® FC 550, Luviquat® FC 552, Luviquat® Excellence, GOHSEFIMER K210™, GOHSENX K-434, and combinations thereof.

Cationic polymers may also include an amino acid monomer (such compounds may also be referred to as polyamino acid compounds). Suitable polyamino acid compounds may include substantially any suitable amino acid monomer groups, for example, including polyarginine, polyhistidine, polyalanine, polyglycine, polytyrosine, polyproline, and polylysine. In example embodiments, polylysine may be a preferred polyamino acid. It will be understood that polylysine may include ε-polylysine and/or α-polylysine composed of D-lysine and/or L-lysine. The polylysine may thus include α-poly-L-lysine, α-poly-D-lysine, ε-poly-L-lysine, ε-poly-D-lysine, and mixtures thereof. The most preferred polylysine is ε-poly-L-lysine. It will further be understood that the polyamino acid compound (or compounds) may be used in any accessible form, e.g., the conjugate acid or base and salt forms of the polyamino acid may be used instead of (or in addition to) the polyamino acid.

The cationic polymer may also (or alternatively) include a derivatized polyamino acid (i.e., a cationic polymer containing a derivatized amino acid monomer unit). For example, the derivatized polyamino acid may include derivatized polyarginine, derivatized polyornithine, derivatized polyhistidine, and derivatized polylysine. CMP compositions including derivatized polyamino acid compounds are disclosed in commonly assigned U.S. Pat. No. 11,492,514.

In certain advantageous embodiments, the polishing composition may include first and second distinct inhibitor compounds. For example, the first inhibitor compound in the composition may include a cationic polymer such as a polyamino acid (with polylysine being preferred) and the second inhibitor compound in the composition may include an amino acid (with glycine, arginine, and a histidine being preferred).

The disclosed polishing compositions may include substantially any suitable concentration of the inhibitor compound and/or topography control agent. In general, the concentration is desirably high enough to provide adequate etch inhibition and topography control, but low enough so that the compound is soluble and so as not to reduce tungsten polishing rates below acceptable levels. By soluble it is meant that the compound is fully dissolved in the liquid carrier or that it forms micelles in the liquid carrier or is carried in micelles. It may be necessary to vary the concentration of the inhibitor compound depending upon numerous various factors, for example, including the solubility thereof, the number of amine groups therein, the length of an alkyl group, the relationship between etch rate inhibition and polishing rate inhibition, the oxidizing agent used, the concentration of the oxidizing agent, and so on. In example embodiments, the concentration of an amine compound in the polishing composition may be in a range from about 1 ppm by weight to about 200 ppm by weight at point of use (e.g., from about 5 ppm to about 100 ppm or from about 10 ppm to about 50 ppm). In example embodiments that include a cationic surfactant, the concentration of the cationic surfactant in the polishing composition may be in a range from about 0.1 ppm by weight to about 50 ppm by weight at point of use (e.g., from about 0.5 ppm to about 20 ppm or from about 1 ppm to about 10 ppm). In example embodiments that include a cationic polymer, the concentration of the cationic polymer in the polishing composition may be in a range from about 0.1 ppm by weight to about 100 ppm by weight at point of use (e.g., from about 1 ppm to about 50 ppm, from about 5 ppm to about 40 ppm, or from about 10 ppm to about 30 ppm).

The polishing composition may optionally further include a biocide. The biocide may include any suitable biocide, for example an isothiazolinone biocide. The amount of biocide in the polishing composition typically is in a range from about 1 ppm to about 50 ppm by weight at point of use or in a concentrate, and preferably from about 1 ppm to about 20 ppm.

In the disclosed embodiments, the copolymer modified colloidal silica particles may be prepared, for example, by bonding a copolymer to the surface of colloidal silica particles in a dispersion. For example, a first neutral acrylate or acrylamide silane monomer may be bonded to the colloidal silica particles by admixing the colloidal silica particles and the first monomer and heating the mixture to a temperature of at least 50 degrees C. In preferred embodiments, the synthesis process is a wet process meaning that the colloidal silica particles are never dried. Moreover, in preferred embodiments, at least 90 percent (e.g., at least 95 percent, at least 98 percent, or at least 99 percent) of the added monomer is bonded to the surface of the silica particles such that less than 10 percent (e.g., less than 5 percent, less than 2 percent, or less than 1 percent) of the added monomer remains in solution after the reaction. A second comonomer (the positively charged comonomer) may be added to the mixture along with an initiator to polymerize the copolymer and obtain the dispersion of copolymer modified colloidal silica particles. In other words the initiator and the second comonomer may be admixed with the monomer modified colloidal silica particles to obtain a dispersion of the copolymer modified colloidal silica particles. The admixture containing the initiator solution may then be optionally heated, for example, to a temperature of at least 50 degrees C to promote the copolymerization.

The disclosed polishing compositions may be prepared by combining one or more CMP polishing additives with the dispersion of the copolymer modified colloidal silica particles. Any suitable techniques may be used; many of which are known to those skilled in the art. The polishing composition may be prepared in a batch or continuous process. Generally, the polishing composition may be prepared by combining the components thereof in any order. The term “component” as used herein includes the individual ingredients (e.g., the colloidal silica, the iron-containing accelerator, the amine compound, etc.).

For example, the polishing composition components (such as an iron-containing accelerator, a stabilizer, an inhibitor, and/or a biocide) may be mixed together with an appropriate amount of water. A dispersion of the copolymer modified colloidal silica particles may then be added to and blended with the mixture. The dispersion may be optionally passed through an ion exchange column prior to adding it to the above mixture. Substantially any suitable blending techniques may be used for achieving adequate mixing. Such blending/mixing techniques are well known to those of ordinary skill in the art. An optional oxidizing agent may be added at any time during the preparation of the polishing composition. For example, the polishing composition may be prepared prior to use, with one or more components, such as the oxidizing agent, being added just prior to the CMP operation (e.g., within about 1 minute, or within about 10 minutes, or within about 1 hour, or within about 1 day, or within about 1 week of the CMP operation). The polishing composition also may also be prepared by mixing the components at the surface of the substrate (e.g., on the polishing pad) during the CMP operation.

The polishing composition may advantageously be supplied as a one-package system comprising the above described copolymer modified colloidal silica particles having the above described physical properties and other optional components. An oxidizing agent may be desirably supplied separately from the other components of the polishing composition and may be combined, e.g., by the end-user, with the other components of the polishing composition shortly before use (e.g., 1 week or less prior to use, 1 day or less prior to use, 1 hour or less prior to use, 10 minutes or less prior to use, or 1 minute or less prior to use). Various other two-container, or three- or more-container, combinations of the components of the polishing composition are within the knowledge of one of ordinary skill in the art.

The polishing composition of the invention may also be provided as a concentrate which is intended to be diluted with an appropriate amount of water prior to use. In such concentrated embodiments, the polishing composition concentrate may include the modified colloidal silica particles, water, and other optional components such as an iron-containing accelerator, a stabilizer, an inhibitor, and a biocide, with or without the oxidizing agent, in amounts such that, upon dilution of the concentrate with an appropriate amount of water, and an optional oxidizing agent if not already present in an appropriate amount, each component of the polishing composition will be present in the polishing composition in an amount within the appropriate ranges recited above for each component. For example, the modified colloidal silica particles and other optional components may each be present in the polishing composition in an amount that is about 2 times (e.g., about 3 times, about 4 times, about 5 times, or even about 10 times) greater than the point of use concentrations recited above for each component so that, when the concentrate is diluted with an equal volume of (e.g., 2 equal volumes of water, 3 equal volumes of water, 4 equal volumes of water, or even 9 equal volumes of water respectively), along with the oxidizing agent in a suitable amount, each component will be present in the polishing composition in an amount within the ranges set forth above for each component. Furthermore, as will be understood by those of ordinary skill in the art, the concentrate may contain an appropriate fraction of the water present in the final polishing composition in order to ensure that other components are at least partially or fully dissolved in the concentrate.

The disclosed polishing compositions may be used to polish substantially any substrate, for example, including a metal layer such as a tungsten or molybdenum layer and a dielectric layer such as a silicon oxide layer. Certain advantageous embodiments may be particularly useful in the polishing of a substrate including at least one metal including tungsten or molybdenum and at least one dielectric material such as silicon oxide. In such applications, the metal layer may be deposited over one or more barrier layers, for example, including titanium and/or titanium nitride (TiN). The dielectric layer may be a metal oxide such as a silicon oxide layer derived from tetraethylorthosilicate (TEOS), porous metal oxide, porous or non-porous carbon doped silicon oxide, fluorine-doped silicon oxide, glass, organic polymer, fluorinated organic polymer, or any other suitable high or low-k insulating layer.

The polishing method of the invention is particularly suited for use in conjunction with a chemical mechanical polishing (CMP) apparatus. Typically, the apparatus includes a platen, which, when in use, is in motion and has a velocity that results from orbital, linear, or circular motion, a polishing pad in contact with the platen and moving with the platen when in motion, and a carrier that holds a substrate to be polished by contacting and moving relative to the surface of the polishing pad. The polishing of the substrate takes place by the substrate being placed in contact with the polishing pad and the polishing composition of the invention and then the polishing pad moving relative to the substrate, so as to abrade at least a portion of the substrate (such as tungsten, titanium, titanium nitride, and/or a dielectric material as described herein) to polish the substrate.

The disclosed embodiments may be particularly well suited for bulk tungsten or molybdenum removal (which are sometimes referred to as first step CMP operations). As known to those of ordinary skill in the art, metal CMP operations commonly include a bulk process that is intended to remove at least a portion the tungsten or molybdenum overlayer (e.g., most or all of the overlayer) and a buff process intended to remove at least a portion of one of the barrier layer(s) (e.g., titanium or titanium nitride) and eliminate defects imparted by the bulk process. In certain advantageous embodiments, the disclosed polishing composition may provide for high planarization efficiency to be achieved for a substrate having a tungsten or molybdenum layer and a dielectric layer. For example, low array erosion, dishing, and/or patterned oxide loss may be achieved using the disclosed compositions.

A substrate may be planarized or polished with the chemical mechanical polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, co-formed products thereof, and mixtures thereof.

The following examples further illustrate the invention but, of course, should not be construed as in any way limiting its scope.

### Example 1

One cationic co-polymer modified colloidal silica dispersion was prepared. An aqueous mixture was prepared including about 6 weight percent colloidal silica particles (having a weight average particle size of about 120 nm) by mixing 1330 grams of deionized water, 522 grams of a colloidal silica dispersion including 23 wt. % colloidal silica, and 134 grams of a pre-hydrolyzed 3% solution of 3-trimethoxysilylpropyl methacrylate (MPS) monomer (equivalent to 2005 ppm and 3.74 μmol per m² of the colloidal silica) without any pH adjustment. The mixture was heated to 75 °C for 14 hours to bond the MPS to the colloidal silica surface and then purged with nitrogen for 30 minutes. An azobisisobutyronitrile (AIBN) initiator solution was then added to the reactor along with 15 grams of a 5% solution of carboxybetaine acrylamide (20 mol percent) as a cationic co-monomer to polymerize with methacrylate on the particle surface. The temperature was maintained at 75 °C for 10 additional hours with continued nitrogen purging. The modified colloidal silica particles had a theoretical modification level of 50 percent of the copolymer while the copolymer had a theoretical comonomer ratio of 20 mole percent of the carboxybetaine acrylamide comonomer.

### Example 2

Various analytical measurements were made on the dispersion prepared in Example 1. These included pH, particle size, zeta potential, isoelectric point (IEP), and Sear's number. First and second control compositions were also evaluated. The first control composition included identical colloidal silica particles modified with bis(trimethoxysilylpropyl) amine at a theoretical modification level of 10%. The second control composition included identical colloidal silica particles modified with MPS at a theoretical modification level of 50% (without the addition of the cationic comonomer). Table 2 lists the pH, particle size, zeta potential, IEP, and Sear's number.

The particle sizes were measured using the Zetasizer® (available from Malvern® instruments). The zeta potential was measured at pH 3.5 using the Colloidal Dynamics Zetaprobe Analyzer®. No Smoluchowski correction was applied. The procedure for measuring the IEP was as described above using a KOH base titration and Zetaprobe Analyzer® zeta potential measurements. The Sear's number was determined via a Sear's titration using the procedure described above.

TABLE 2

| | | Particle | Zeta | | |
|---|---|---|---|---|---|
| | | Size | Potential | Isoelectric | Sear's |
| Composition | pH | (nm) | (mV) | Point | Number |
| Control 1 | 3.2 | 124 | 89 | 7.3 | 2.3 |
| Control 2 | 7.3 | 123 | 4 | 4.0 | 1.5 |
| 1A | 3.1 | 148 | 68 | 6.6 | 1.2 |

As is apparent from the results set forth in Table 2, composition 1A has a significantly reduced Sear's number as compared to the control compositions.

### Example 3

Three polishing compositions were prepared using the colloidal silica dispersions described above in Examples 1 and 2. Each polishing composition included 0.0445 wt. % malonic acid, 0.0206 wt. % ferric nitrate nonahydrate, 13 ppm by weight epsilon poly-L-lysine, 17 ppm by weight Proxel AQ preservative, 3.0 wt. % hydrogen peroxide and 0.3 wt. % of a colloidal silica. The pH of each composition was adjusted to 2.7 using potassium hydroxide.

The CMP performance of each composition was evaluated using a Reflexion® CMP polishing tool (Applied Materials) with an E6088 polishing pad (Entegris) and in-situ conditioning using a Saesol C1 conditioner at 4.5 lbs. Tungsten and TEOS polishing rates were obtained by polishing 300 mm blanket tungsten and TEOS wafers at a downforce of 3.0 psi, a platen speed of 100 rpm, a head speed of 101 rpm, and a slurry flow rate was 200 mL/min. Blanket wafer polishing rates (removal rates) are shown in Table 3A. Patterned wafer polishing performance was evaluated by polishing 300 mm 2kÅ PureWafer tungsten patterned wafers at the same conditions. Each patterned wafer was polished to optical end-point plus 30 percent overpolish. Patterned wafer performance was evaluated using atomic force microscope (AFM) profilometer measurements across 1×1 and 1×1 micron line features. The patterned wafer polishing data is shown in Table 4B.

TABLE 3A

| | Blanket W | Blanket TEOS | W:TEOS |
|---|---|---|---|
| Composition | Rate (Å/min) | Rate (Å/min) | Selectivity |
| Control 1 | 3650 | 33 | 111 |
| Control 2 | 2553 | 64 | 40 |
| 3A | 3371 | 24 | 141 |

TABLE 3B

| | Patterned W Rate | Oxide | Dishing | Erosion | Dishing | Erosion |
|---|---|---|---|---|---|---|
| Composition | (Å/min) | Loss (Å) | 1 × 1 (Å) | 1 × 1 (Å) | 3 × 1 (Å) | 3 × 1 (Å) |
| Control 1 | 3499 | 37 | 62 | 276 | 133 | 583 |
| Control 2 | 2621 | 21 | 289 | −3 | 343 | 559 |
| 3A | 4043 | 28 | 91 | 94 | 157 | 281 |

As is apparent from the results in set forth in Tables 3A and 3B, composition 3A including the cationic copolymer modified colloidal silica achieved a higher patterned tungsten removal rate as well as reduced erosion and better overall planarity (the sum of erosion and dishing) than either of the control compositions.

It will be understood that the recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical mechanical polishing composition comprising:
a liquid carrier;
colloidal silica particles dispersed in the liquid carrier; and
a silicon containing polymer covalently bonded to a surface of the colloidal silica particles, the polymer having a first acrylate silane or acrylamide silane group and a second positively charged nitrogen containing group such that the colloidal silica particles have a positive charge in the polishing composition.

2. The composition of claim 1, wherein the polymer comprises a copolymer having first and second comonomers, the first comonomer having the first acrylate silane or acrylamide silane group and the second comonomer having the second positively charged nitrogen containing group.

3. The composition of claim 2, wherein:
the first comonomer comprises a methacrylate group; and
the second comonomer comprises a quaternary amine group.

4. The polishing composition of claim 2, wherein the copolymer comprises from about 4 mole percent to about 40 mole percent of the second comonomer.

5. The composition of claim 1, wherein the polymer is a homopolymer comprising a monomer having both the first acrylate silane or acrylamide silane group and the second positively charged nitrogen containing group.

6. The composition of claim 5, wherein:
the first group comprises a methacrylate group; and
the second group comprises a quaternary amine group.

7. The composition of claim 1, wherein the colloidal silica particles have a theoretical modification level of the polymer of greater than about 20 percent.

8. The composition of claim 1, wherein the colloidal silica particles have Sear's number of less than about 1.6.

9. The composition of claim 1, wherein the colloidal silica particles have an IEP of greater than about 6.

10. The composition of claim 1, wherein the colloidal silica particles have a zeta potential of greater than about 30 mV in the polishing composition.

11. The composition of claim 1, comprising from about 0.01 to about 1 weight percent of the colloidal silica particles at point of use.

12. The composition of claim 1, further comprising an oxidizer and an iron-containing compound, wherein the iron-containing compound comprises a soluble iron containing catalyst and a polycarboxylic acid stabilizer bound to the soluble iron containing catalyst.

13. The composition of claim 1, wherein the composition further comprises:
from about 0.01 wt. % to about 1 wt. % of the colloidal silica particles at point of use;
from about 1 to about 100 ppm by weight of a cationic polymer at point of use; and
an iron containing compound contributing from about 1 ppm to about 100 ppm iron at point of use.

14. A method of chemical mechanical polishing a substrate, the method comprising:
contacting the substrate with a polishing composition comprising;
a liquid carrier;
colloidal silica particles dispersed in the liquid carrier; and
a silicon containing polymer covalently bonded to a surface of the colloidal silica particles, the polymer having a first acrylate silane or acrylamide silane group and a second positively charged nitrogen containing group such that the colloidal silica particles have a positive charge in the polishing composition;
moving the polishing composition relative to the substrate; and
abrading the substrate to remove at least a portion of a metal or a dielectric material from the substrate and thereby polish the substrate.

15. The method of claim 14, wherein the substrate comprises a tungsten metal layer or a molybdenum metal layer, and abrading removes at least a portion of the tungsten metal or the molybdenum layer from the substrate.

16. A method for preparing a chemical mechanical polishing composition, the method comprising:
admixing colloidal silica particles and a silicon containing compound including an acrylate or an acrylamide silane monomer to obtain a colloidal silica admixture;
covalently bonding the silicon containing compound to the colloidal silica particles to obtain a modified colloidal silica admixture; and
admixing a second monomer including a positively charged nitrogen group with the modified colloidal silica admixture; and
copolymerizing the silicon containing compound and the second monomer to obtain a dispersion of copolymer modified colloidal silica particles.

17. The method of claim 16, further comprising admixing at least one chemical compound with the dispersion of copolymer modified colloidal silica particles to obtain a chemical mechanical polishing composition.

18. The method of claim 16, wherein:
the silicon containing compound comprises a methacrylate group; and
the second monomer comprises a quaternary amine group.

19. The method of claim 16, wherein the covalently bonding comprises heating the colloidal silica admixture to a temperature of at least 50 degrees C.

20. The method of claim 16, wherein the copolymerizing comprises:
admixing an initiator with the second monomer and the modified colloidal silica admixture to obtain an initiator containing admixture; and
heating the initiator containing admixture to a temperature of at least 50 degrees C.
